(19) United States
(12) Patent Application Publication
(10) Pub. No.: US 2025/0034703 A1
(43) Pub. Date: Jan. 30, 2025

(54) PRECURSOR DELIVERY VESSEL, PRECURSOR DELIVERY SYSTEM, AND PRECURSOR DEPOSITION APPARATUS

(71) Applicant: ASM IP Holding B.V., Almere (NL)

(72) Inventors: Quentin Nikitas Nicolas Lionel Eric Tricas, Schaerbeek (BE); Alessandro Viva, Leuven (BE); Theodorus G.M. Oosterlaken, Oudewater (NL); Jeroen Fluit, Amsterdam (NL)

(21) Appl. No.: 18/781,473

(22) Filed: Jul. 23, 2024

Related U.S. Application Data
(60) Provisional application No. 63/515,501, filed on Jul. 25, 2023.

(51) Int. Cl. C23C 16/448

(52) U.S. Cl. CPC C23C 16/4483

(57) ABSTRACT

A vapor phase precursor delivery system for delivering a vapor phase precursor for depositing a layer in a vapor phase deposition apparatus is disclosed. The precursor delivery vessel is constructed and arranged to store a solid precursor and to deliver a vapor phase precursor at a vessel outlet. The system being provided with a plate provided with holes to allow for gas transport between the chamber and the part of the vessel where the solid precursor is stored.

### CROSS-REFERENCE TO RELATED APPLICATION(S)

This Application claims the benefit of U.S. Provisional Application 63/515,501 filed on Jul. 25, 2023, the entire contents of which are incorporated herein by reference.

### FIELD OF INVENTION

The disclosure generally relates to a precursor delivery system to provide a vapor phase precursor from the vessel, the system being provided with a holder constructed and arranged to hold the vessel and constructed and arranged to deliver a vapor phase precursor at a vapor phase outlet. The disclosure may also relate to a precursor delivery vessel constructed and arranged to store a solid precursor and to deliver a vapor phase precursor at a vessel outlet.

The disclosure further relates to a precursor deposition apparatus, such as for example a vertical furnace comprising a precursor delivery system for depositing a layer on a substrate.

### BACKGROUND OF THE DISCLOSURE

A vapor phase precursor delivery system for delivering a vapor phase precursor for depositing a layer on a substrate in a reactor of a vapor phase deposition apparatus may exhibit certain challenges. One of these challenges may be that the precursor delivery system may deliver to less vapor and the precursor delivery may in fact become a bottle neck for the productivity of the deposition apparatus.

The precursor delivery system may be delivering to less precursor because the vapor pressure of the solid precursor may be very low. The delivery of the precursor may be dependent on the level of the top surface of the solid precursor in the vessel. Since the level of the solid precursor in the vessel during use of the system may go down the solid precursor sublimated in the system may become less. The top surface of the solid precursor may also be carved by the flow of the gas so that the gas flow touches less solid precursor and the quantity of the solid precursor sublimated in the system may become less.

### SUMMARY OF THE DISCLOSURE

It may be an objective to provide a precursor delivery vessel constructed and arranged to store a solid precursor and to deliver a vapor phase precursor.

Accordingly, there may be provided a precursor delivery vessel constructed and arranged to store a solid precursor and to deliver a vapor phase precursor at a vessel outlet. The vessel outlet may be constructed and arranged in fluid communication with a vessel inlet via a chamber being defined by a top plate, and a bottom plate. The bottom plate may be constructed and arranged to be supported on the top surface of the solid precursor and to be moveable with the top surface of the solid precursor in the vessel. The bottom plate may be provided with holes to allow for gas transport between the chamber and the part of the vessel where the solid precursor is stored and to allow sublimated precursor from the solid precursor to enter the chamber.

According to a further embodiment, a precursor delivery system to provide a vapor phase precursor from a solid precursor may be provided. The system may comprise a vessel constructed and arranged for storing solid precursor and provided with a vessel inlet and a vessel outlet. The vessel outlet may be constructed and arranged in fluid communication with the vessel inlet via a chamber constructed and arranged to be supported on top of the solid precursor and move with the solid precursor level in the vessel. The system may further comprises a holder constructed and arranged to hold the vessel, an inert gas source constructed an arranged to connect to the vessel inlet to deliver inert gas to the vessel, and a vapor phase outlet constructed and arranged to connect to the vessel outlet for delivery of the vapor phase precursor. The chamber may be defined by a top plate, and a bottom plate constructed and arranged to be supported on the surface of the solid precursor. The bottom plate may be provided with holes to allow for gas transport between the part of the vessel where the solid precursor is stored and the chamber to allow sublimated precursor from the solid precursor to enter the chamber.

According to yet a further embodiment there may be provided a delivery system to provide a vapor phase precursor from a solid precursor. The system may comprise a holder constructed and arranged to hold a vessel constructed and arranged to store solid precursor and provided with a vessel inlet and a vessel outlet; an inert gas source constructed an arranged to connect to the vessel inlet to deliver inert gas to the vessel; and a vapor phase outlet constructed and arranged to connect to the vessel outlet for delivery of the vapor phase precursor. The holder may be constructed and arranged for allowing movement of the vessel.

According to yet a further embodiment a vapor phase deposition apparatus may be provided. The apparatus may comprise a vapor phase precursor delivery system for delivering a vapor phase precursor for depositing a layer on a substrate. The apparatus may be a vertical furnace comprising a reactor constructed and arranged to load a boat with a plurality of substrates. The vapor phase precursor delivery system may be constructed and arranged for delivering a vapor phase precursor for depositing a layer on the plurality of substrates in the reactor.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1A and 1B disclose a precursor delivery system according to the prior art.

FIG. 2 discloses a precursor delivery system according to an embodiment.

FIG. 3 disclose a top view on a bottom plate for the delivery system of FIG. 2.

FIG. 4 discloses a precursor delivery system provided in a holder constructed and arranged to hold the vessel.

FIG. 5 discloses how a vessel can be moved to a holder constructed and arranged to hold the vessel.

FIG. 6 discloses a precursor delivery system according to a further embodiment.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

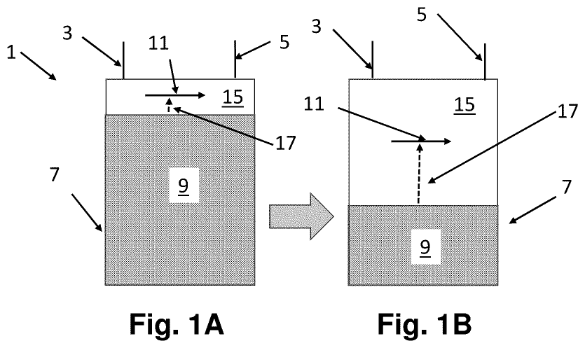

FIGS. 1A and 1B disclose a vapor phase precursor delivery system 1 comprising: a vessel inlet 3 and a vessel outlet 5 according to the prior art. The vapor phase precursor delivery system 1 may comprise a vessel 7 constructed and arranged for storing a precursor 9. A gas flow 11 may be created between the gas inlet 3 and the gas outlet 5 for example with an inert gas like nitrogen through a headspace 15 above the precursor 9 level in the vessel 7. The gas flow 11 may pick up some precursor 9 sublimated 17 into the gas flow 11 which may be transported out of the vessel 7 via the vessel outlet 5.

The sublimation of the precursor 9 may be dependent on the level of the precursor 9 in the vessel 7. Since the level of the precursor 9 in the vessel 7 during use of the system 1 may be lowered from a relatively full vessel 7 in FIG. 1A to a relatively empty vessel 7 in FIG. 1B the quantity of the precursor 9 sublimated 17 in the system 1 may also become lower. This may be caused by a headspace 15 becoming larger creating a larger vertical concentration gradient in the headspace 15 lowering sublimation from the precursor 9. The gas flow 11 may be further away from the precursor 9 and the gas flow 11 may therefore have a lower concentration of precursor when it reaches the vessel outlet 5. A precursor deposition apparatus comprising the vapor phase precursor delivery system and receiving a lower concentration of precursor may be less productive.

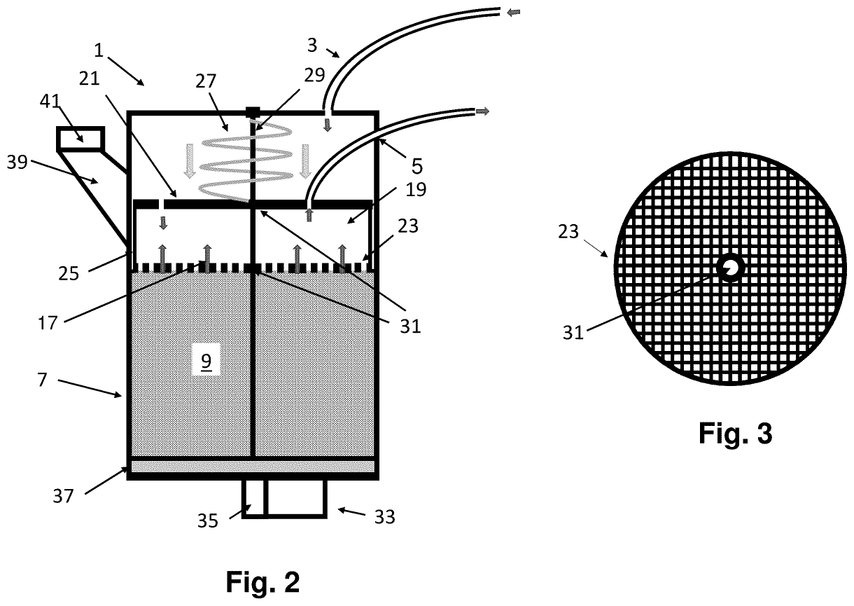

FIG. 2 discloses a precursor delivery system 1 according to an embodiment. A precursor delivery vessel 7 may be constructed and arranged to store and sublimate a solid precursor 9 and to deliver a vapor phase precursor at a vessel outlet 5. The vessel outlet 5 may be constructed in fluid communication with a chamber 19 being provided with a top plate 21 and a bottom plate 23. The bottom plate 23 may be constructed and arranged to be supported on the top surface of the solid precursor 9. The chamber 19 may be moveable with the top surface of the solid precursor 9 in the vessel 7.

FIG. 3 disclose a top view on a bottom plate for the delivery system of FIG. 2. The bottom plate 23 may be provided with holes to allow for gas transport between the chamber 19 and the part of the vessel 7 where the solid precursor 9 is stored. The holes need to be adapted to the grain size of the solid precursor so that the bottom plate remains supported on the solid precursor 9.

Sublimated precursor from the solid precursor 9 may enter the chamber 19 through the holes in the bottom plate 23. The bottom plate 23 may be a meshed structure to allow for uniform sublimation of the solid precursor.

The chamber 19 may be provided with a wall 25 connected to the top plate 21 and the bottom plate 23 to define the chamber 19. The wall 25 may be circular. Alternatively, the wall may be omitted so that the vessel inner surface of the vessel 7 defines the chamber 19.

The vessel may be provided with a spring 27, for example between an inner surface of the vessel 7 and the top plate 21. The spring 27 may press the bottom plate 23 against a top surface of the solid precursor 9 in the vessel 7. When the solid precursor 9 sublimating the spring 27 may unwind while continuously pressing the bottom plate against the solid precursor 9.

The vessel 7 may be provided with a linear guiding surface in the interior of the vessel to guide the chamber 19 linearly. The guiding may be necessary for the chamber 19 during its movement through the interior of the vessel 7 to avoid that it gets stuck in the vessel. The guiding surface may be provided on the outside surface of a guiding post 29 which may be centrally located in the vessel 7. The guiding post 29 may match a guiding hole 31 in the bottom plate 23 and/or the top plate 21.

Alternatively, the guiding surface may be provided by the interior surface of the vessel 7. The interior surface may be cooperating with the top plate 21, bottom plate 23 or wall 25 for guiding the chamber 19.

If the solid precursor 9 is not sublimating uniformly the chamber 19 may get stuck in the vessel 7. This may happen if the flow to vessel outlet 5 is carving an optimal path through the solid precursor 9 which minimizes its flow resistance. The walls of this carved path may block the bottom plate 23 for further moving down if precursor is sublimated. In the end this may result in reduced sublimation of the precursor 9 and not sublimating precursor remaining in the vessel 7 which may both be unwanted.

The vessel 7 may comprise an actuator 33 constructed and arranged to move the solid precursor 9 in the vessel. The solid precursor may be in the form of grains and by moving the vessel 7 and the grains, the grains may redistribute themself in the vessel 7. The top surface of the solid precursor 9 may thereby become/remain flat. The bottom plate 23 may start/keep moving again. Sublimation 17 may also be enhanced.

The actuator 33 may be constructed and arranged to provide a linear movement. The actuator 33 may be constructed and arranged to provide a reciprocating movement. The reciprocating movement may have a frequency between 0.1 and 10,000 Hz.

The actuator 33 may be provided with a controller 35 to switch the movement on and off between 1 and 0.01 Hz. This may save energy or reduce harmonic vibrations in the tool. The actuator may be constructed and arranged to move the vessel to move the solid particles in the vessel 7.

To provide the linear reciprocating movement the actuator 33 may be a linear motor. The linear motor may comprise a coil and a magnet. The coil may be powered with an alternating current to provide the reciprocating movement. The linear motor may exert a force on a weight just to create a vibrational motion to the vessel 7. The vessel may be supported with flexible spring or rubber to allow the vibration while not transmitting it to other components.

The vessel 7 may be provided with a vessel inlet 3 constructed in fluid communication with the vessel outlet 5 via the chamber 19 and via at least one flexible tube to provide a flow of a pickup gas through the chamber 19 to transport the vapor phase precursor out of the chamber 19 while allowing movement of the chamber in the vessel. The vessel 7 may be provided with a heater 37. The heater 37 may be constructed and arranged to sublimate the solid precursor 9.

The solid precursor 9 may be a metal chloride, such as Hafnium tetrachloride (HfCl4), Tantalum pentachloride (TaCl5), Molybdenum pentachloride (MoCl5), Zirconium tetrachloride (ZrCl4), or Molybdenum dichloride dioxide (MoO2Cl2) to deposit a transition metal. Molybdenum dichloride dioxide (MoO2Cl2) may have a relatively high vapor pressure so that its behavior may be different.

The vessel may be provided with a level measurement device to measure the level of the precursor 9. When the level of the precursor 9 becomes too low the vessel 7 may be refilled.

The vessel 7 may be provided with a lifting device constructed and arranged for moving the chamber 19 up when the solid precursor is substantially finished and a refill may be necessary. The lifting device may charge the spring 27 again. The lifting device may have a linear drive for moving the chamber 19 up. The linear drive may be for example a motor and a spindle cooperating with a moving nut provided to the chamber 19. A controller may be provided to control the movement of the chamber 19 by the lifting device.

The vessel 7 may be provided with a fill port 39 for filling the vessel 7 with new precursor 9 when the chamber 19 is moved to the top position by the lifting device and provided with a lid 38 to cover the fill port 39. The new precursor may be provided in the vessel 7 underneath the chamber 19. The chamber 19 may be lowered on the top surface of the solid precursor 9 and normal operation may be presumed.

The chamber 19 may be constructed and arranged for creating a constant gas flow in the chamber 19 at a substantial constant level from a surface of the precursor 9 in the vessel 7. The level of the precursor 9 in the vessel 7 during use of the system 1 may be lowered from a relatively full vessel 7 to a relatively empty vessel 7. The quantity of the precursor 9 vaporized 17 in the system however may be kept constant since the gas flow is kept at a constant distance from the surface of the precursor 9 since the chamber 19 is moving with the precursor level. This is advantageous because the quantity of precursor in the gas flowing out of the gas outlet 5 remains constant as well.

The connecting tube of the vessel outlet 5 may be flexible and constructed and arranged to allow for movement of the chamber 19 with respect to the vessel 7 and to allow for the movement of the vessel 7 caused by the actuator 33. The connecting tube of the vessel inlet 3 may also be flexible and constructed and arranged to allow for movement of the vessel 7 caused by the actuator 33. For example, the connecting tube may be made from flexible material e.g. rubber or polytetrafluoroethylene (PTFE).

The vessel 7 may be mounted with a flexible material e.g. rubber or polytetrafluoroethylene (PTFE) in a frame. This allows for movement of the vessel 7 by the actuator 33 and allows the solid precursor 9 to rearrange itself in the vessel 7.

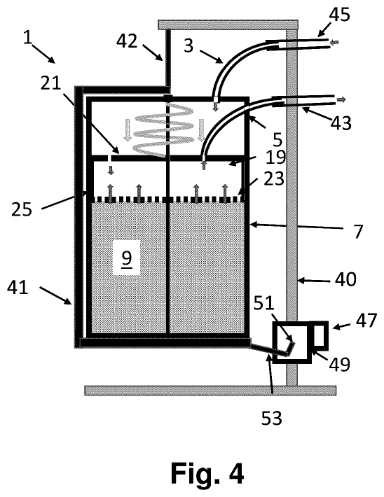

FIG. 4 discloses a precursor delivery system 1 provided with a holder 41 constructed and arranged to hold the vessel 7. The holder 41 may be suspended movably from a support frame 40 via a flexible rope 42 or with hinges.

The vessel 7 may be constructed and arranged for storing solid precursor 9 and provided with a vessel outlet 5. The vessel outlet 5 may be constructed and arranged in fluid communication with a chamber 19 constructed and arranged to be supported on top of the solid precursor 9 and move with the solid precursor level in the vessel 7. The chamber 19 may be defined by a top plate 21, and a bottom plate 23 constructed and arranged to be supported on the surface of the solid precursor 9. The bottom plate 23 may be provided with holes to allow for gas transport between the part of the vessel 7 where the solid precursor 9 is stored and the chamber 19 to allow sublimated precursor from the solid precursor to enter the chamber.

The support frame 40 may be provided with vapor phase outlet 43 constructed and arranged to be connectable to the vessel outlet 5 for delivery of the vapor phase precursor. This allows for easy replacement of the vessel 7 from the holder 41 if the vessel 7 is empty and may be replaced with a new full vessel 7.

The system 1 may be provided with a rotational actuator 49 constructed and arranged to move the solid precursor 9 in the vessel 7 by exerting a force between the support frame 40 and the holder 41 to move the vessel 7 and the precursor 9. The rotational actuator 49 may be a motor connected with a pair of hinges 53 to the vessel 7 to transfer the rotational motor into a linear reciprocating movement.

The support frame 40, actuator 49 and holder 41 are constructed and arranged to move the vessel 7 with a rotational or tilting movement so as to evenly spread the precursor 9 in the vessel 7. The actuator 49 may be constructed and arranged to rotate between 1 and 100 RPM. The actuator 49 may be provided with a controller 47 to switch the movement on and off between 1 and 0.01 Hz. This may save energy or reduce harmonic vibrations in the tool.

The support frame 40 may be provided with an inert gas source 45 constructed an arranged to be connectable the vessel inlet 3 to deliver inert gas to the vessel 7. The inert gas source 45 may be connected with a flexible tube to the chamber 19 or the vapor phase holder outlet 43 may be connected with a flexible tube to the chamber 19 so as to allow for movement of the vessel 7.

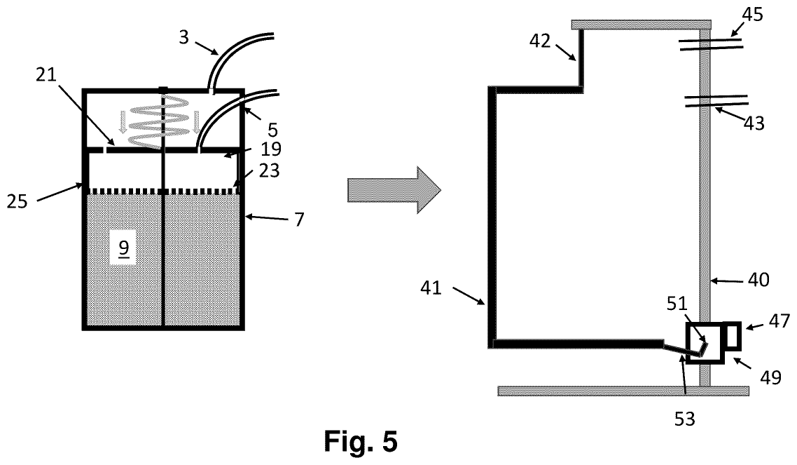

FIG. 5 discloses how a vessel 7 can be moved to a holder 41 constructed and arranged to hold the vessel 7 to form the precursor delivery system of FIG. 4. The support frame 40 may be provided with vapor phase outlet 43 constructed and arranged to be connectable to the vessel outlet 5 of the vessel 7 for delivery of the vapor phase precursor 9. The support frame 40 may be provided with an inert gas source 45 constructed an arranged to be connectable the vessel inlet 3 of the vessel 7 to deliver inert gas to the vessel 7. This allows for easy replacement of the vessel 7 from the holder 41 if the vessel 7 is empty and may be replaced with a new full vessel 7.

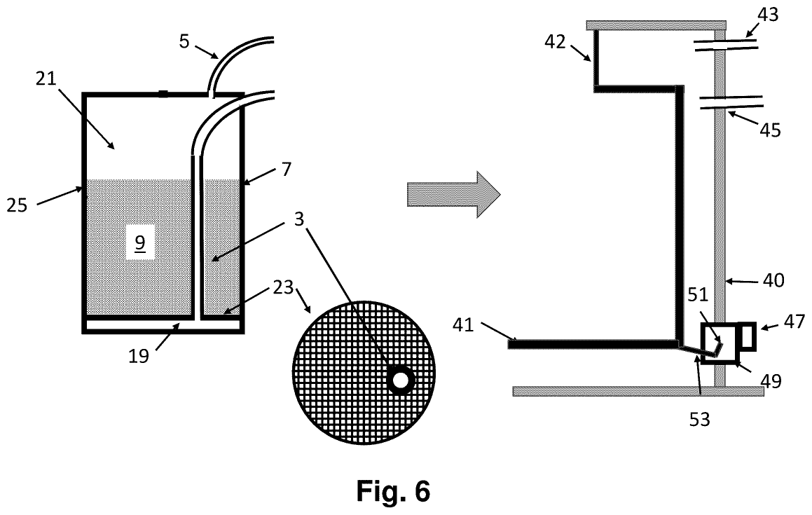

FIG. 6 discloses a precursor delivery system according to a further embodiment. A precursor delivery vessel 7 may be constructed and arranged to store and sublimate a solid precursor 9 and to deliver a vapor phase precursor at a vessel outlet 5. The vessel 7 may be provided with a vessel inlet 3 constructed in fluid communication with a chamber 19 via at least a tube to provide a flow of a pickup gas to the solid precursor 9 via holes in a bottom plate 23 and the chamber 19. The vessel outlet 5 may be constructed in fluid communication with the chamber 19 through the solid precursor 9 and the holes in the bottom plate 23. The holes need to be adapted to the grain size of the solid precursor so that the solid precursor 9 remains supported on the bottom plate 23. The bottom plate 23 may be a meshed structure to allow for uniform sublimation of the solid precursor.

The vessel 7 may be provided with a heater. The heater may be constructed and arranged to sublimate the solid precursor 9.

The vessel 7 can be moved into a holder 41 constructed and arranged to hold the vessel 7. The support frame 40 may be provided with vapor phase outlet 43 constructed and arranged to be connectable to the vessel outlet 5 of the vessel 7 for delivery of the vapor phase precursor 9. The support frame 40 may be provided with an inert gas source 45 constructed an arranged to be connectable the vessel inlet 3 of the vessel 7 to deliver inert gas to the vessel 7. This allows for easy replacement of the vessel 7 from the holder 41 if the vessel 7 is empty and may be replaced with a new full vessel 7.

The holder 41 may be suspended movably from the support frame 40 via a flexible rope 42 or with a hinge. A rotational actuator 49 constructed and arranged to move the solid precursor 9 in the vessel 7 by exerting a force between the support frame 40 and the holder 41 may be provided to move the vessel 7 and the precursor 9. The rotational actuator 49 may be a motor connected with a pair of hinges 53 to the vessel 7 to transfer the rotational motor into a linear reciprocating movement. The support frame 40, actuator 49 and holder 41 may be constructed and arranged to move the vessel 7 with a rotational or tilting movement so as to evenly spread the precursor 9 in the vessel 7.

The vapor phase precursor delivery system 1 may be used in a vapor phase deposition apparatus for delivering a vapor phase precursor for depositing a layer on a substrate. The vapor phase deposition apparatus may be a vertical furnace comprising a reactor constructed and arranged to load a boat with a plurality of substrates and the vapor phase precursor delivery system is constructed and arranged for delivering a vapor phase precursor for depositing a layer on the substrates in the reactor. A vertical furnace suitable to use the vapor phase precursor delivery system 1 may be described in U.S. Pat. No. 7,732,350 B2 for example incorporated herein by reference.

The illustrations presented herein are not meant to be actual views of any particular material, structure, or device, but are merely idealized representations that are used to describe embodiments of the disclosure.

The implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

1. A precursor delivery vessel constructed and arranged to store a solid precursor and to deliver a vapor phase precursor at a vessel outlet, which is constructed in fluid communication with a chamber being defined by a top plate, and a bottom plate constructed and arranged to be supported on a top surface of the solid precursor and to be moveable with the top surface of the solid precursor in the vessel, wherein the bottom plate is provided with holes to allow for gas transport between the chamber and a part of the vessel where the solid precursor is stored and to allow sublimated precursor from the solid precursor to enter the chamber.

2. The vessel according to claim 1, wherein the bottom plate is a meshed structure to allow for uniform sublimation of the solid precursor.

3. The vessel according to claim 1, wherein the chamber is further defined by a wall connected to the top plate and the bottom plate.

4. The vessel according to claim 1, wherein the vessel is provided with a spring between an inner surface of the vessel and the chamber to press the bottom plate against the top surface of the solid precursor in the vessel.

5. The vessel according to claim 1, wherein the vessel is provided with a linear guiding surface in an interior of the vessel to guide the chamber linearly during its movement through the interior of the vessel.

6. The vessel according to claim 1, wherein the vessel comprises an actuator constructed and arranged to move the solid precursor in the vessel.

7. The vessel according to claim 6, wherein the actuator is constructed and arranged to provide a linear movement.

8. The vessel according to claim 6, wherein the actuator is constructed and arranged to provide a reciprocating movement.

9. The vessel according to claim 6, wherein the actuator is constructed and arranged to provide a reciprocating movement with a frequency between 0.1 and 10,000 Hz.

10. The vessel according to claim 6, wherein the actuator is provided with a controller to switch movement on and off between 1 and 0.01 Hz.

11. The vessel according to claim 1, wherein the vessel is provided with a vessel inlet constructed in fluid communication with the vessel outlet via the chamber and via at least one flexible tube to provide a flow of a pick-up gas through the chamber to transport the vapor phase precursor out of the chamber while allowing movement of the chamber in the vessel and the vessel is provided with a heater constructed and arranged to hold and sublimate a metal chloride, such as Hafnium tetrachloride (HfCl₄), Tantalum pentachloride (TaCl₅), Molybdenum pentachloride (MoCl₅), Zirconium tetrachloride (ZrCl₄), or Molybdenum dichloride dioxide (MoO₂Cl₂) to deposit a transition metal.

12. The vessel according to claim 1, wherein the vessel comprises:
a lifting device constructed and arranged to lift the chamber up when the solid precursor is substantially finished;
a fill port for refilling the vessel with solid precursor when the chamber is lifted up; and,
a lid to cover the fill port.

13. A precursor delivery system to provide a vapor phase precursor from a solid precursor, the system comprising:
a vessel constructed and arranged for storing solid precursor and provided with a vessel outlet, which vessel outlet is constructed and arranged in fluid communication with a chamber constructed and arranged to be supported on top of the solid precursor and move with a level of the solid precursor in the vessel,
a holder constructed and arranged to hold the vessel; and
a vapor phase outlet constructed and arranged to connect to the vessel outlet for delivery of the vapor phase precursor, wherein the chamber is being defined by a top plate, and a bottom plate constructed and arranged to be supported on the top surface of the solid precursor and the bottom plate is provided with holes to allow for gas transport between a part of the vessel where the solid precursor is stored and the chamber to allow sublimated precursor from the solid precursor to enter the chamber.

14. The system according to claim 13, wherein the system comprises an actuator constructed and arranged to move the solid precursor in the vessel.

15. The system according to claim 13, wherein the system is provided with a support frame supporting an actuator and the holder and the actuator is constructed and arranged to exert a force between the support frame and the holder to move the vessel and the solid precursor.

16. The system according to claim 15, wherein the support frame, actuator and holder are constructed and arranged to move the vessel with a rotational or tilting movement.

17. A precursor delivery system to provide a vapor phase precursor from a solid precursor, the system comprising:
a holder constructed and arranged to hold a vessel for storing and sublimating a solid precursor;
an inert gas source constructed an arranged to connect to the vessel to deliver inert gas to the vessel; and
a vapor phase outlet constructed and arranged to connect to the vessel for delivery of the vapor phase precursor, wherein the holder is constructed and arranged for allowing movement of the vessel.

18. The system according to claim 17, wherein the system comprises an actuator constructed and arranged to exert a force on the vessel to move the vessel.

19. A precursor deposition apparatus comprising a vapor phase precursor delivery system according to claim 13 for delivering a vapor phase precursor for depositing a layer on a substrate.

20. The apparatus according to claim 19, wherein the apparatus is a vertical furnace comprising a reactor constructed and arranged to load a boat with a plurality of substrates and the vapor phase precursor delivery system is constructed and arranged to deliver a vapor phase precursor for depositing a layer on the plurality of substrates in the reactor.
